(19) United States
(12) Patent Application Publication
(10) Pub. No.: US 2026/0234793 A1
(43) Pub. Date: Aug. 13, 2026

(54) SUBSTRATE PROCESSING APPARATUS, SUBSTRATE PROCESSING METHOD, METHOD OF MANUFACTURING SEMICONDUCTOR DEVICE, RECORDING MEDIUM, AND TRANSFER MACHINE

(71) Applicant: KOKUSAI ELECTRIC CORPORATION, Tokyo (JP)

(72) Inventors: Takeshi KASAI, Toyama (JP); Akinori ISHII, Toyama (JP); Toshiki FUJINO, Toyama (JP)

(73) Assignee: KOKUSAI ELECTRIC CORPORATION, Tokyo (JP)

(21) Appl. No.: 19/639,462

(22) Filed: Apr. 6, 2026

Related U.S. Application Data
(63) Continuation of application No. PCT/JP2023/046744, filed on Dec. 26, 2023.

(51) Int. Cl. C23C 16/44; C23C 16/455; C23C 16/458; C23C 16/52; H10P 72/00; H10P 72/10; H10P 72/30

(52) U.S. Cl. CPC C23C 16/4405; C23C 16/4412; C23C 16/45563; C23C 16/4584; C23C 16/52; H10P 72/0402; H10P 72/12; H10P 72/3302

(57) ABSTRACT

A technique capable of reducing particles adhering to a substrate is provided includes a process chamber that processes a substrate in a state of being held by a substrate holder; a transfer chamber which is adjacent to the process chamber and in which the substrate holder can be arranged; and an injector that is arranged in the transfer chamber, is configured to be movable along a longitudinal direction of a column of the substrate holder in the transfer chamber, and injects gas toward the column.

### CROSS-REFERENCE TO RELATED APPLICATION

This application is a Bypass Continuation Application of PCT International Application No. PCT/JP2023/046744, filed on December 26, 2023, the entire contents of which are incorporated herein by reference.

### BACKGROUND

### FIELD

The present disclosure relates to a substrate processing apparatus, a substrate processing method, a method of manufacturing a semiconductor device, a recording medium, and a transfer machine.

### DESCRIPTION OF THE RELATED ART

In substrate processing in a semiconductor device manufacturing step, for example, a vertical substrate processing apparatus that collectively processes a plurality of substrates (semiconductor silicon wafers) may be used. In this type of substrate processing apparatus, a boat (substrate holder) that holds the plurality of substrates in multiple stages in a horizontal posture while aligning the substrates with the center thereof is used. The boat includes a plurality of retainers (columns) that holds a substrate.

### SUMMARY

In the film-forming processing, a thin film is formed on a surface of a substrate, and a thin film is also formed on a surface of a boat. For example, at the time of unloading the processed substrate, a thin film formed on the boat may be peeled and fallen from the column to become particles and adhere to the substrate.

The present disclosure provides a technique capable of reducing particles adhering to a substrate.

According to one aspect of the present disclosure, a technique is provided that includes:
(a) a process chamber that processes a substrate in a state of being held by a substrate holder;
(b) a transfer chamber which is adjacent to the process chamber and in which the substrate holder can be arranged; and
(c) an injector that is arranged in the transfer chamber, is configured to be movable along a longitudinal direction of a column of the substrate holder in the transfer chamber, and injects gas toward the column.

### BRIEF DESCRIPTION OF THE DRAWINGS

FIG. 1 is an oblique perspective view of a substrate processing apparatus suitably used in an embodiment of the present disclosure.

FIG. 2 is a schematic perspective view of a transfer machine suitably used in the embodiment of the present disclosure, and is a view for describing transfer to a boat by the transfer machine.

FIG. 3 is a schematic perspective view of the transfer machine suitably used in the embodiment of the present disclosure, and is a view for describing gas injection by an injector.

FIG. 4 is a top view of the transfer machine and the boat illustrated in FIG. 3, and is a view illustrating a positional relationship between the boat and the injector at the time of gas injection.

FIG. 5 is a side view of a sensor rod illustrated in FIG. 3, and is a view illustrating a detailed positional relationship of the injector.

FIG. 6 is a flowchart illustrating a substrate processing step applied in the embodiment of the present disclosure.

### DETAILED DESCRIPTION

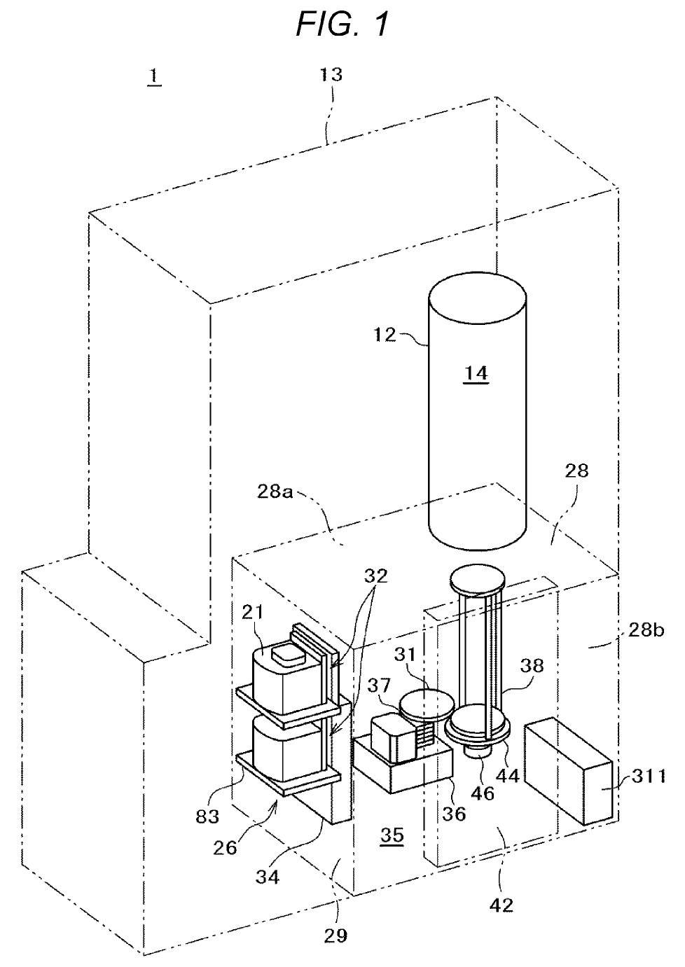

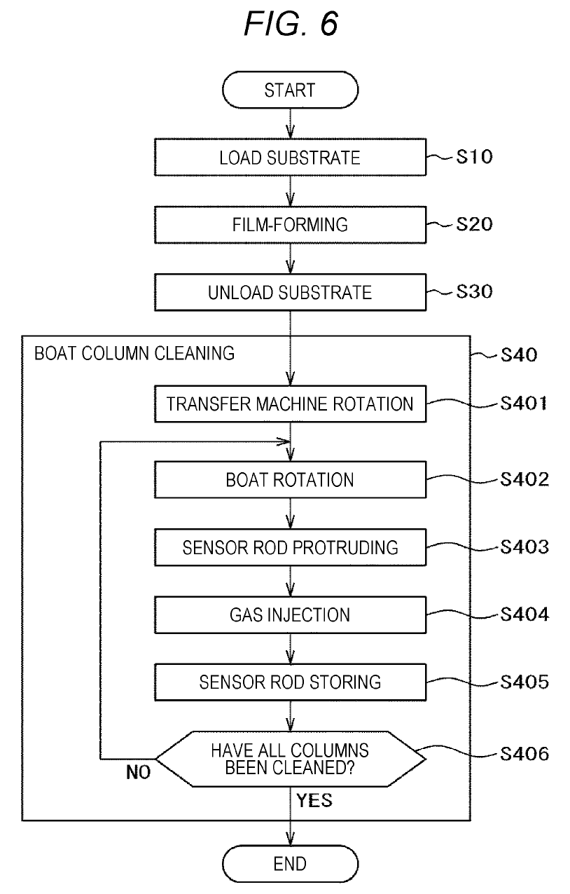

An embodiment of the present disclosure will be described below mainly with reference to FIGS. 1 to 6. Note that the drawings used in the following description are all schematic, and a dimensional relationship between elements, a ratio between elements, and the like illustrated in the drawings do not necessarily coincide with actual ones. In addition, between a plurality of drawings, the dimensional relationships between the elements, the ratios between the elements, and the like do not necessarily coincide with each other. Unless otherwise noted in the specification, each element is not limited to one in number and thus may be two or more in number.

### Outline of substrate processing apparatus

A substrate processing apparatus described in the present embodiment is used in a semiconductor device manufacturing step, and heats a substrate to be processed with a heater in a state where the substrate is housed in a process chamber to perform processing (heat processing). More specifically, the substrate processing apparatus described in the present embodiment is a vertical substrate processing apparatus that simultaneously processes a plurality of substrates in a state where the plurality of substrates is stacked at predetermined intervals in the vertical direction.

An example of the substrate to be subjected to the processing by the substrate processing apparatus is a semiconductor wafer substrate (Hereinafter, simply referred to as a “wafer”.) on which a semiconductor device is fabricated. Examples of the heat processing performed by the substrate processing apparatus include film formation by oxidation, diffusion, annealing, reflow and densification, thermal chemical vapor deposition (CVD) reaction, film quality improvement (treatment) processing, and the like.

### 1 Configuration of substrate processing apparatus

The entire device will be described with reference to FIG. 1. FIG. 1 illustrates a main part of a substrate processing apparatus.

A substrate processing apparatus 1 includes a housing 13. A pod 21 which is a sealed type substrate container is loaded into the substrate processing apparatus 1 and unloaded from the substrate processing apparatus 1 by an in-process transfer apparatus (not illustrated).

A sub housing 28 is disposed over a rear end in a lower portion on a rear side in the front-rear direction in the housing 13. On a front wall 29 of the sub housing 28, a pair of wafer loading/unloading ports 32 for loading/unloading a wafer 31 into/from the sub housing 28 is opened by being arranged in two upper and lower stages in the vertical direction. A pod opener 26 is provided to each of the wafer loading/unloading ports 32 in the upper and lower stages.

The pod opener 26 includes a placement table 33 on which the pod 21 is placed, and an opening/closing mechanism 34 that opens and closes a lid of the pod 21. The pod opener 26 is configured to open and close a wafer inlet/outlet of the pod 21 by opening and closing the lid of the pod 21 placed on the placement table 33 by the opening/closing mechanism 34.

The sub housing 28 constitutes a transfer chamber (charging chamber, loading area)35 that is airtight from a space in which the pod opener 26 is disposed. A transfer machine 36 is installed in a front region of the transfer chamber 35. The transfer machine 36 includes the required number (five in the drawing) of wafer placement plates (substrate grippers) 37 for holding the wafers 31. The wafer placement plate 37 can linearly move in the horizontal direction, can rotate in the horizontal direction, and can ascend and descend in the vertical direction. The transfer machine 36 is configured to charge a boat (substrate holder) 38 with the wafer 31 and to discharge the wafer 31 from the boat 38. The wafer placement plate 37 is also referred to as a hand, an end effector, a chuck, a fork, or a tweezer, and can be configured by, for example, five placement plates.

A vertical processing furnace 12 is installed above the transfer chamber 35. A process chamber 14 is formed inside the processing furnace 12, and a lower end of a furnace opening portion at a lower side of the process chamber 14 is opened, and opened and closed by a furnace opening shutter (not illustrated). The process chamber 14 performs heat processing on the wafer 31 held by a boat 38.

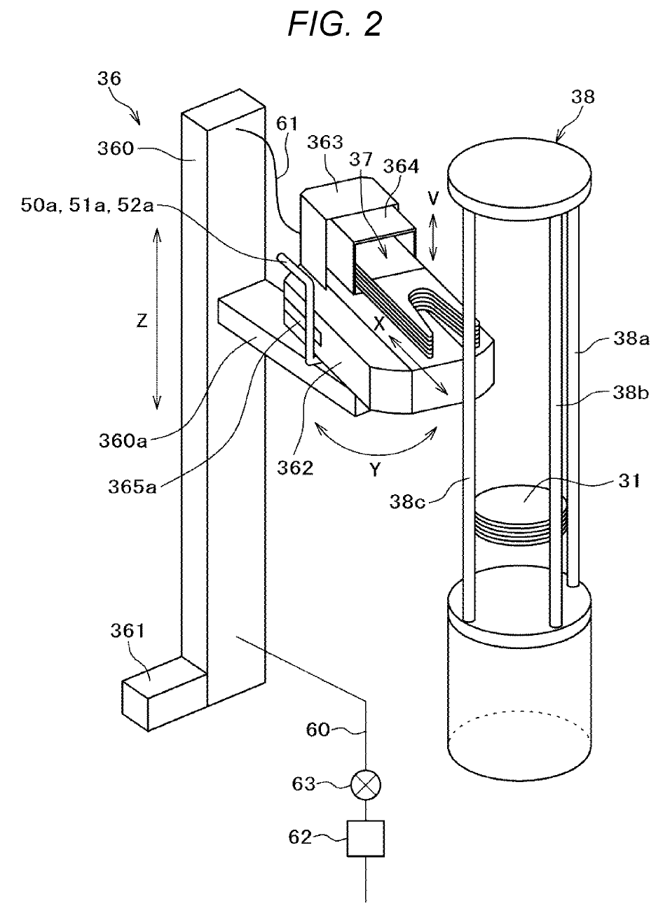

A boat elevator 42 for lifting and lowering the boat 38 is installed on a side surface of the sub housing 28. A seal cap 44 serving as a lid body is horizontally attached to an arm (not illustrated) connected to a lifting platform of the boat elevator 42. The seal cap 44 vertically supports the boat 38, and can airtightly close the furnace opening portion in a state where the boat 38 is charged into the processing furnace 12. The transfer chamber 35 is adjacent to the process chamber 14, and loads and unloads the wafers 31 together with the boat 38 to and from the process chamber 14. The boat 38 is configured to hold a plurality of (for example, about 50 or more and 175 or less) wafers 31 in multiple stages in a horizontal posture while aligning the wafers 31 at the center thereof. As illustrated in FIG. 2, the boat 38 includes columns 38a to 38c as columns for holding the wafers 31. Grooves (slots) for holding the wafers 31 are provided in the columns 38a to 38c.

On the side of the seal cap 44 opposite to the process chamber 14, a rotation mechanism 46 for rotating the boat 38 around the central axis corresponding to the center of the wafer 31 is installed. The rotation shaft of the rotation mechanism 46 penetrates the seal cap 44 and is connected to the boat 38. The rotation mechanism 46 is configured to rotate the boat 38, thereby rotating the wafer 31.

A clean unit (not illustrated) is disposed at a position (the first side surface 28a side of the sub housing 28) facing the boat elevator 42 side (the second side surface 28b side of the sub housing 28). The clean unit is configured by a supply fan and a dustproof filter so as to supply cleaned air or clean air that is inert gas. The first side surface 28a (that is, the first side surface of the transfer chamber 35) of the sub housing 28 has a blowout port for clean air. A notch alignment device (not illustrated) serving as a substrate alignment device that aligns the position of the wafer 31 in a circumferential direction can be disposed between the transfer machine 36 and the clean unit.

The clean air blown out from the clean unit is distributed to the notch alignment device, the transfer machine 36, and the boat 38, then partially sucked by a local exhaust duct (or a common exhaust duct) or the like provided on the second side surface of the transfer chamber 35, and exhausted to the outside of the housing 13 through the exhaust duct. The second side surface 28b (that is, the second side surface of the transfer chamber 35) of the sub housing 28 has an exhaust port. The other part is blown into the transfer chamber 35 again by the clean unit.

A configuration example of the transfer machine will be described with reference to FIG. 2. FIG. 2 illustrates a state at the time of transferring the wafers 31 to the boat 38 by the transfer machine 36. That is, the wafer placement plate (end effector) 37 of the transfer machine 36 faces the columns 38a and 38c of the boat 38.

The transfer machine 36 includes a guide 360 provided along the vertical direction (Z-axis direction), a Z-axis direction driver 361, a Y-axis rotation driver 362, an X-axis direction driver 363, and a V-axis direction driver 364. The drivers 361 to 364 can be rephrased as a drive system.

The Z-axis direction driver 361 is provided at the lower end or the upper end of the guide 360 to move a mount 360a in the up-down direction (Z-axis direction, vertical direction) along the guide 360.

The Y-axis rotation driver 362 is installed on the upper surface of the mount 360a so as to be rotatable in the Y-axis direction in order to horizontally rotate clockwise or counterclockwise (rotate around the Y-axis) while supporting the X-axis and the Y-axis of the X-axis direction driver 363 so as to be orthogonal to each other. Since the pod 21 is usually arranged between the direction of the boat 38 and the opposite direction as viewed from the Y-axis, a rotation range of about 180 degrees is sufficient.

The X-axis direction driver 363 is provided integrally with or inside the Y-axis rotation driver 362 in order to move the V-axis direction driver 364 forward and backward in the horizontal direction (X-axis direction) while supporting the V-axis direction driver 364. In the X-axis, a direction in which the wafer placement plate 37 moves so as to protrude from the Y-axis rotation driver 362 to enter the boat 38 or the pod 21 is defined as “front”.

The V-axis direction driver 364 is provided in the X-axis direction driver 363, and is configured to be able to adjust an interval between five wafer placement plates 37 in the Z-axis direction while horizontally supporting the wafer placement plates.

As a result, the transfer machine 36 can discharge the wafers 31 from the pod 21 by the wafer placement plate 37 and charge the wafers into the boat 38. Then, after an arbitrary processing is performed on the wafers 31 in the processing furnace 12, the transfer machine 36 can discharge the wafers 31 from the boat 38 by the wafer placement plate 37 and charge the pod 21 with the wafers. Additionally, the Y-axis rotation driver 362 has an outer shape having a rotation radius equal to or slightly larger than the minimum rotation radius around the Y-axis of the wafer placement plate 37 and the V-axis direction driver 364. For example, the length of the Y-axis rotation driver 362 in the X-axis direction is equal to or slightly larger than the combined length of the wafer placement plate 37 and the V-axis direction driver 364, and the side portion has a side surface parallel to the X-axis.

The transfer machine 36 further includes sensor rods 50a and 50b serving as arms provided on both side surfaces of the Y-axis rotation driver 362, and advance and retreat drivers 365a and 365b that move the sensor rods 50a and 50b in the X-axis direction.

The sensor rods 50a and 50b are configured to extend upward along both side surfaces of the Y-axis rotation driver 362 to substantially the same height as any of the wafer placement plates 37, and be bent in a direction opposite to the mounting direction of the wafer placement plate 37 with respect to the X-axis direction driver 363, that is, substantially at a right angle to the rear side of the X-axis. The sensor rods 50a and 50b hold fiber sensors 51a and 51b serving as mapping sensors and injectors 52a and 52b.

Light transmission/reception portions 54a and 54b of the fiber sensors 51a and 51b are attached to distal ends of the sensor rods 50a and 50b, respectively. The fiber sensors 51a and 51b are a pair of transmission type sensors in which one transmits light and the other receives the light, and can be arranged such that an optical path (optical axis) formed between the light transmission/reception portions 54a and 54b is parallel to a tangent of the wafer 31. The fiber sensors 51a and 51b perform mapping of counting the number of the wafers 31 with which the pod 21 or the boat 38 is charged and detecting normality or abnormality such as jumping out of the wafers by detecting blocking of the optical path. When the sensor rods 50a and 50b move forward, the optical axes remain aligned and are horizontal. The sensor rods 50a and 50b may be connected to pass through the Y-axis rotation driver 362 so as to interlock with each other, and in this case, only one of the advance and retreat drivers 365a and 365b may be provided.

In addition, the advance and retreat drivers 365a and 365b are arranged on both side surfaces of the Y-axis rotation driver 362, and support the sensor rods 50a and 50b so as to be movable in the X-axis direction between the protruding position and the storing position. That is, the wafer placement plate 37 and the sensor rods 50a and 50b are arranged in opposite directions back to back with respect to the Y-axis rotation driver 362, and can move independently of each other on the X-axis. The sensor rods 50a and 50b are movable along the longitudinal direction (up-down direction, Z direction) of the columns 38a to 38c of the boat 38 by the Z-axis direction driver 361.

As a result, the transfer machine 36 can perform mapping of the wafer 31 in the pod 21 by the fiber sensors 51a and 51b. Then, the transfer machine 36 can perform mapping of the wafers 31 in the boat 38 by the fiber sensors 51a and 51b.

The injectors 52a and 52b are arranged along the sensor rods 50a and 50b. A gas supply pipe 60 is connected to at least one of the injectors 52a and 52b via a flexible piping 61 or the like. The gas supply pipe 60 is provided with a mass flow controller (MFC) 62 and a valve 63 serving as an on-off valve in the order from the upstream side of the gas flow. A clean gas serving as a cleaning gas is supplied to the injectors 52a and 52b. As the clean gas, for example, nitrogen (N₂) gas constituting the atmosphere in the transfer chamber 35 can be used. The flexible piping 61 is laid appropriately through the guide 360 or a cover thereof, the mount 360a, and the inside of the Y-axis rotation driver 362, and has flexibility that does not hinder the operation of the Y-axis rotation driver 362 and the advance and retreat drivers 365a and 365b (to be described later).

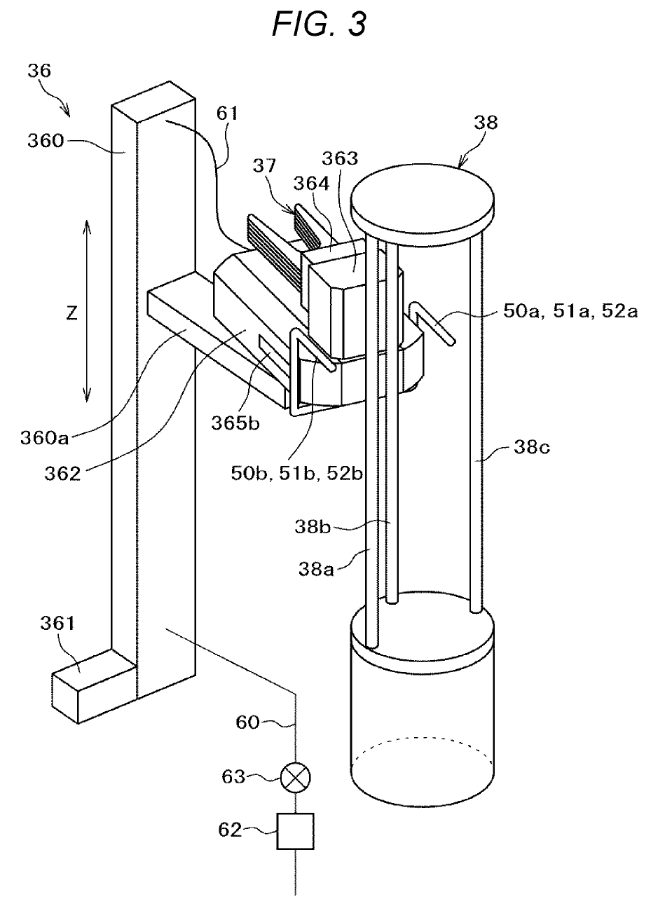

Hereinafter, assuming that the gas supply pipe 60 is connected to the injector 52a, cleaning of the boat 38 by the injector 52a will be described with reference to FIGS. 3 to 5. FIG. 3 illustrates a state in which the columns 38a to 38c of the boat 38 are cleaned by the injector 52a of the transfer machine 36. In this state, the boat 38 is not charged with the wafer 31. Although FIG. 5 illustrates an example of the sensor rod 50a, the sensor rod 50b has a similar configuration.

As illustrated in FIG. 3, the sensor rods 50a and 50b of the transfer machine 36 are moved in a direction approaching the boat 38 by the Y-axis rotation driver 362, that is, in a direction in which the X-axis faces the center of the boat 38. In addition, the boat 38 is rotated by the rotation mechanism 46, and any one of the columns 38a to 38c of the boat 38 is arranged at a position closest to the transfer machine 36. In FIG. 3, the column 38b is arranged at a position closest to the Y-axis of the transfer machine 36, that is, on the X-axis.

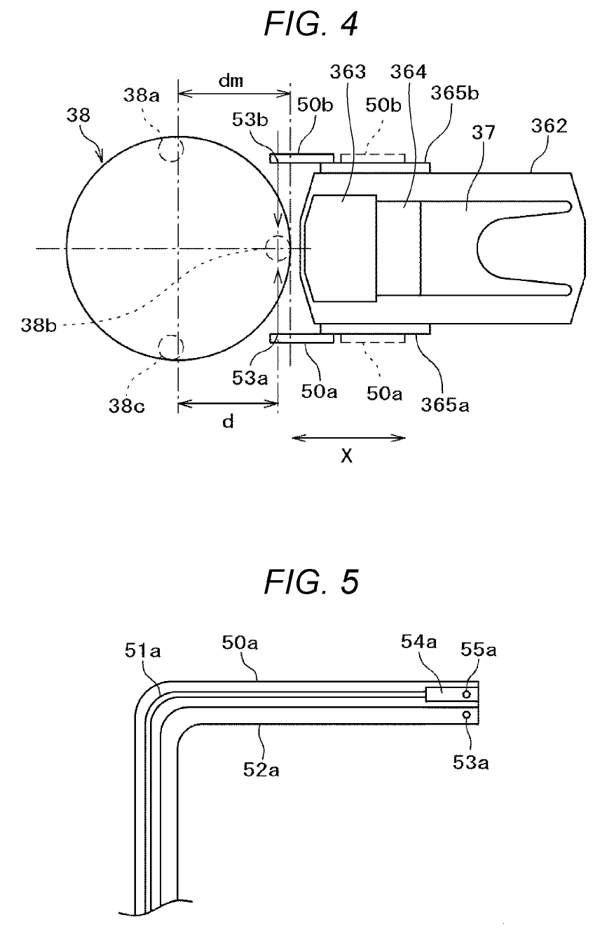

As illustrated in FIG. 4, the injection holes 53a and 53b of the injectors 52a and 52b are arranged on distal end sides of the sensor rods 50a and 50b, respectively. In other words, the injection holes 53a and 53b of the injectors 52a and 52b are provided side by side with the light transmission/reception portions 54a and 54b of the fiber sensors 51a and 51b. As illustrated in FIG. 5, the injector 52a is a pipe bent into a shape similar to that of the sensor rod 50a, and a horizontal portion thereof is arranged below the sensor rod 50a. The injector 52a is provided with the injection hole 53a on a side surface near the distal end, and the other end is connected to the flexible piping 61. An optical window 55a of the light transmission/reception portion 54a and the injection hole 53a are vertically juxtaposed so as to face substantially in the same direction.

The sensor rods 50a and 50b indicated by broken lines in FIG. 4 are at the retreat positions. The rotation radius of the sensor rods 50a and 50b around the Y-axis at this time is smaller than that of the Y-axis rotation driver 362. On the other hand, the sensor rods 50a and 50b indicated by solid lines are at the protruding positions, and the rotation radius of the sensor rods 50a and 50b around the Y-axis at this time is larger than that of the Y-axis rotation driver 362.

The sensor rods 50a and 50b are moved to the protruding positions on the boat 38 side by the advance and retreat drivers 365a and 365b, and any one of the columns 38a to 38c is arranged between the injection holes 53a and 53b. In FIG. 4, the column 38b is arranged between the injection holes 53a and 53b of the injectors 52a and 52b. In other words, the positions of the injectors 52a and 52b in the X direction approach to a position where a distance (d) from the central axis of the boat 38 is shorter than the maximum distance (dm) from the central axis to the columns 38a to 38c. As an example, it is assumed that the injection direction of the injection holes 53a and 53b is a horizontal direction orthogonal to the X axis, and the distance d is substantially equal to the distance from the central axis to the center of the columns 38a to 38c. As a result, the injectors 52a and 52b can be brought close to a column to be cleaned without being brought into contact with the column to be cleaned, and the gas can be injected toward the center of the column to be cleaned. The advance and retreat drivers 365a and 365b constitute an injector driver that changes the distance from the central axis of the boat 38 to the injectors 52a and 52b. Furthermore, it can also be said that the Y-axis rotation driver 362 or the entire transfer machine 36 is an injector driver that moves the injectors 52a and 52b. As a result, it is not necessary to separately provide a driver that moves the injectors 52a and 52b up and down and forward and backward.

The injection hole 53a injects gas for cleaning toward any one of the columns 38a to 38c from a tangential direction of a circle centered on the central axis of the boat 38 and passing through the columns 38a to 38c. FIG. 4 illustrates an example in which the gas for cleaning is injected toward the column 38b. Since the gas is blown from a tangential direction of the boat 38, the gas sufficiently flows between slots (grooves) provided in the columns 38a to 38c, and the particle source can be removed. This makes it possible to suppress generation of particles from the grooves. In addition, when the gas is injected in the tangential direction of the boat 38, the gas flows around the column and then immediately goes out of the boat 38, so that the peeled particle source can be discharged without adhering to the boat 38.

The injector 52a moves along the longitudinal direction (up-down direction, central axis direction) of the columns 38a to 38c of the boat 38 by the Z-axis direction driver 361, and injects gas toward the columns 38a to 38c. In other words, the injector driver is configured to be able to move the injectors 52a and 52b along the columns 38a to 38c extending in the central axis direction of the boat 38. As a result, the injectors 52a and 52b can move up and down over between the uppermost stage and the lowermost stage of the slots for holding the wafers 31 of the columns 38a to 38c.

Note that in a case where the boat 38 does not have a structure such as a ring on the lateral of the columns 38a to 38c, one of the injectors 52a and 52b can be further brought closer to the columns 38a to 38c by shifting the X axis from the direction in which the X axis faces the center of the boat 38. For example, in a case where the distance from the Y-axis to the injection hole 53a is made substantially equal to the distance from the Y-axis to the center of the column 38b in FIG. 4, the injection hole 53a can face the side surface of the column 38b by rotating the Y-axis so as to bring the injector 52a closest to the column 38b until immediately before contacting the column 38b. At this time, since the injection hole 53a injects from a slightly inner peripheral side of a tangent of a circle centered on the central axis of the boat and passing through the column, the gas can be applied to the bottom of the groove provided in the column 38b.

The gas for cleaning injected from the injectors 52a and 52b physically removes solid object (particle source) that causes particles from the columns 38a to 38c (by wind pressure). Therefore, the gauge pressure of the gas for cleaning injected from the injectors 52a and 52b is preferably 100 kPa or more. This makes it possible to enhance the peeling effect of the particle source. When the gas flow or pressure on the surfaces of the columns 38a to 38c is temporally changed, the peeling effect can be further enhanced. For example, the supply flow rate or the flow velocity of the gas in the injection holes 53a and 53b of the injectors 52a and 52b may be temporally changed by the MFC 62. Alternatively, a flow rate or a flow velocity at which the injected gas becomes a vibration flow (turbulent flow) may be set, and the injectors 52a and 52b may be supported by an elastic body such as a spring so that vibration easily occurs, or a vortex generator may be arranged in front of the injection hole. Alternatively, one or more of each shaft of the transfer machine 36 and the rotation shaft of the rotation mechanism 46 may be swung to change the relative position and orientation of the injectors 52a and 52b with respect to the columns 38a to 38c.

When mapping is performed on the wafers 31 processed in the process chamber 14 and discharged to the transfer chamber 35, a small amount of inert gas serving as cooling gas may be discharged from the injectors 52a and 52b. That is, the injectors 52a and 52b have discharge holes for discharging the inert gas to the fiber sensors 51a and 51b, respectively, and the light transmission/reception portions 54a and 54b are cooled with the inert gas, whereby mapping can be performed on a higher temperature wafer.

Any one of the injectors 52a and 52b preferably injects gas in a direction from the first side surface toward the second side surface of the transfer chamber 35. As a result, it is possible to enhance the effect of removing the particle source removed from the columns 38a to 38c from the transfer chamber 35 by the clean gas from the clean unit. At this time, the injector 52a or 52b whose injection direction is reverse to the flow of the clean air can be omitted. Alternatively, when the valve 63 and the piping 61 are provided for each of the injectors 52a and 52b and the gas is alternately injected, the cleaning gas can be applied to both side surfaces of the columns 38a to 38c, and the removal effect can be expected to be enhanced.

A controller 311 is configured as a computer including a central processing unit (CPU) and a memory. The memory is configured as a computer-readable recording medium.

A control program for controlling an operation of the substrate processing apparatus, a process recipe in which procedures, conditions and the like of substrate processing to be described later are described and the like are readably stored in the memory. The process recipe is combined to cause a controller 311 to execute procedures in a substrate processing step to be described later and obtain a predetermined result, and functions as a program. Hereinafter, the process recipe, the control program, and the like are also collectively and simply referred to as a program. In the present specification, the term “program” may include only the process recipe alone, only the control program alone, or both of these.

The CPU is configured to read and execute the control program from the memory and read the process recipe. The CPU is configured to control the wafer transfer operation, the mapping operation, and the cleaning operation by the transfer machine 36, and the rotation and rotation speed adjustment operation of the boat 38 by the rotation mechanism 46 according to the content of the read process recipe. The CPU is further configured to control an elevating operation of the boat 38 by the boat elevator 42, inert gas flow rate adjusting operation by the MFC 62, an opening/closing operation of the valve 63, and the like.

### 2 Substrate processing step

An outline of a substrate processing step of processing a substrate using the substrate processing apparatus 1 serving as a semiconductor manufacturing apparatus will be described. The substrate processing step is, for example, a process for manufacturing a semiconductor device. Note that, in the following description, the operation and processing of each portion constituting the substrate processing apparatus 1 are controlled by the controller 311.

### Substrate loading step: S10

When being supplied to the substrate processing apparatus 1, the pod 21 is transferred to the placement table 33.

An opening side end surface of the pod 21 placed on the placement table 33 is pressed against an opening edge portion of the wafer loading/unloading port 32 on the front wall 29 of the sub housing 28, and a lid of the pod 21 is removed by the opening/closing mechanism 34 to open the wafer inlet/outlet.

When the pod 21 is opened by the pod opener 26, the sensor rods 50a and 50b of the transfer machine 36 are moved to protruding positions (directions approaching the pod 21) by the advance and retreat drivers 365a and 365b. Then, the sensor rods 50a and 50b are moved up and down at a constant speed by the Z-axis direction driver 361, and the wafers 31 are mapped by the fiber sensors 51a and 51b, whereby the wafers 31 in the pod 21 are sequentially detected.

After the mapping operation is completed, the sensor rods 50a and 50b are returned to the retreating positions. Then, by sequentially repeating forward movement, upward movement, and backward movement of the wafer placement plate 37, turning of the Y-axis rotation driver 362, and forward movement, downward movement, and backward movement of the wafer placement plate 37, the wafers 31 are picked up from the inside of the pod 21 through the wafer loading/unloading port 32, and are charged into the boat 38.

After the charging is completed, the lower end portion of the processing furnace 12 closed by the furnace opening shutter is opened by the furnace opening shutter. Subsequently, the seal cap 44 is raised (boat-up) by the boat elevator 42, so that the boat 38 holding the wafers 31 is loaded from the transfer chamber 35 into the processing furnace 12.

### Film-forming step: S20

After loading, heat processing is performed on the wafers 31 in the process chamber 14 in the processing furnace 12.

### Substrate unloading step: S30

Next, the boat 38 on which the heat-processed wafers 31 are placed is unloaded (boat unload) from the process chamber 14 to the transfer chamber 35. Then, the boat 38 cools the heat-processed wafers 31.

After cooling, the sensor rods 50a and 50b of the transfer machine 36 are moved to the protruding positions by the advance and retreat drivers 365a and 365b. Then, the sensor rods 50a and 50b are moved up and down by the Z-axis direction driver 361, and the mapping operation of the wafer 31 is performed by the fiber sensors 51a and 51b. Then, when the mapping is completed, the sensor rods 50a and 50b return to the storing positions, and the wafers 31 are transferred by the wafer placement plate 37 and unloaded to the pod 21. Thereafter, the pod 21 is unloaded to the outside of the housing 13.

### Boat column cleaning step: S40

### Transfer machine rotation step: S401

After all the wafers 31 held by the boat 38 are unloaded to the pod 21, the sensor rods 50a and 50b are rotated by the Y-axis rotation driver 362 so as to face the boat 38. In other words, the wafer placement plate 37 is rotated by the Y-axis rotation driver 362 so as to face opposite to the boat 38.

### Boat rotation step: S402

The boat 38 is rotated by the rotation mechanism 46 such that one column among the columns 38a to 38b of the boat 38 is at a position closest to the transfer machine 36.

### Sensor rod protruding step: S403

The sensor rods 50a and 50b protrude toward the boat 38 by the advance and retreat drivers 365a and 365b, and the injection holes 53a and 53b of the injectors 52a and 52b are arranged at predetermined positions.

### Gas injection step: S404

The injectors 52a and 52b move up and down between the uppermost stage and the lowermost stage of the slot for holding the wafer 31 of the boat 38 by the Z-axis direction driver 361 while injecting the cleaning gas to one column among the columns 38a to 38c.

### Sensor rod storing step: S405

The sensor rods 50a and 50b are retracted from the boat 38 by the advance and retreat drivers 365a and 365b.

### Determination step: S406

It is determined whether all the columns 38a to 38c have been cleaned. If all the columns 38a to 38c have not been cleaned (NO), the processing returns to step S402. As a result, the boat 38 sequentially rotates with respect to the columns 38a to 38c of the boat 38 such that the columns 38a to 38c are positioned in the injection direction of the injectors 52a and 53b, and the columns 38a to 38c are cleaned. When the cleaning of all the columns 38a to 38c has been completed (YES), the processing ends.

The boat column cleaning is executed during a time (for example, during a time in which pod 21 is being discharged) in which the boat 38 is not being transferred in a home position (a state in which the boat is fully lowered and is in the transfer chamber 35). This does not affect the throughput of the substrate processing (obtained by dividing the number of processed substrates per processing by the time from the charging to the discharging of the pod 21).

According to the present embodiment, one or a plurality of effects described below can be obtained.

a As compared with the porous nozzle, gas can be injected from one injection hole at a close distance and at a large flow velocity, and the peeling effect of the particle source on the surface of the column of the boat can be enhanced.

b Automatic maintenance can be performed more frequently than manual maintenance by an air gun, and the particle suppression effect can be enhanced.

Although the embodiments of the present disclosure have been specifically described above, the present disclosure is not limited to the above-described embodiments, and various modifications can be made without departing from the scope of the present disclosure. For example, the injectors 52a and 52b are not limited to those attached to the sensor rods 50a and 50b, and may be provided directly to the advance and retreat drivers 365a and 365b. The fiber sensors 51a and 51b are not limited to those attached to the sensor rods 50a and 50b, and may be attached to the injectors 52a and 52b also serving as the sensor rods.

In the embodiment described above, an example of performing the heat processing using a batch type substrate processing apparatus that processes a plurality of substrates at a time has been described. The present disclosure is not limited to the above-described embodiments, and can be appropriately applied to a case where heat processing is performed by use of a single wafer type substrate processing apparatus that processes one or more substrates at a time, for example. In addition, in the above-described embodiments, an example has been described in which a film is formed by use of a substrate processing apparatus including a hot wall type processing furnace. The present disclosure is not limited to the above-described embodiments, and is suitably applicable to a case where heat processing is performed by use of a substrate processing apparatus including a cold wall type processing furnace.

Even in a case where such substrate processing apparatuses are each used, the corresponding processing can be performed in accordance with a processing procedure and processing conditions similar to those in the above-described embodiments, leading to obtainment of an effect similar to that in the above-described embodiments.

According to the present disclosure, it is possible to reduce particles adhering to a substrate.

What is claimed is:

1. A substrate processing apparatus comprising:
a process chamber that processes a substrate in a state of being held by a substrate holder;
a transfer chamber which is adjacent to the process chamber and in which the substrate holder is able to be arranged;
an injector that is arranged in the transfer chamber, is configured to be movable along a longitudinal direction of a column of the substrate holder in the transfer chamber, and injects gas toward the column; and
a rotation mechanism that rotatably supports the substrate holder about a central axis corresponding to a center of the substrate,
wherein an injection hole of the injector injects the gas for cleaning toward the column from a tangential direction of a circle centered on the central axis and passing through the column.

2. A substrate processing apparatus according to claim 1 further comprising
a controller capable of controlling the rotation mechanism so that the plurality of columns is sequentially positioned in an injection direction of the injector with respect to the columns and controlling the injector so as to inject the gas.

3. A substrate processing apparatus according to claim 2 further comprising
an injector driver that changes a distance from the central axis to the injector,
wherein the injector approaches a position where a distance from the central axis of the substrate holder is shorter than a maximum distance from the central axis to the column.

4. The substrate processing apparatus according to claim 2, further comprising an injector driver that changes a distance from the central axis to the injector.

5. The substrate processing apparatus according to claim 4,
wherein the substrate holder holds a plurality of substrates in multiple stages along the central axis, and
the injector driver is configured to be able to move the injector along the column extending in the central axis direction.

6. The substrate processing apparatus according to claim 4, wherein the injector driver is a transfer machine that transfers a substrate to and from the substrate holder.

7. The substrate processing apparatus according to claim 5, wherein the injector driver is a rotation driver provided in a transfer machine, and an injection hole of the injector is arranged on a distal end side of an arm rotated by the rotation driver.

8. The substrate processing apparatus according to claim 3, wherein the gas is inert gas, and the substrate processing apparatus physically removes solid object that causes particles from the column.

9. The substrate processing apparatus according to claim 5, wherein the injector driver is a rotation driver for advancing and retreating a mapping sensor with respect to a substrate, and an injection hole of the injector is provided side by side with a mapping sensor rotated about a predetermined rotation axis parallel to a plane perpendicular to the central axis by the rotation driver.

10. The substrate processing apparatus according to claim 3, wherein gauge pressure of the gas injected from the injector is 100 kPa or more.

11. The substrate processing apparatus according to claim 1, wherein a flow rate or a flow velocity of gas in an injection hole of the injector is temporally changed.

12. The substrate processing apparatus according to claim 1, wherein cooling gas is discharged from the injector when mapping is performed on the substrate processed in the process chamber and discharged to the transfer chamber.

13. The substrate processing apparatus according to claim 1, wherein the transfer chamber has a first side surface having a blowout port for clean air and a second side surface facing the first side surface and having an exhaust port, and the injector injects gas in a direction from the first side surface toward the second side surface.

14. A substrate processing method comprising:
(a) processing a substrate in a state being held by a substrate holder in a process chamber;
(b) loading and unloading a substrate together with the substrate holder between the process chamber and a transfer chamber arranged adjacent to the process chamber; and
(c) injecting, by an injector arranged in the transfer chamber and configured to be movable along a longitudinal direction of a column of the substrate holder in the transfer chamber, gas toward the column.

15. A method of manufacturing a semiconductor device comprising the method of claim 14.

16. A non-transitory computer-readable recording medium storing a program that causes, by a computer, a substrate processing apparatus to perform a process comprising the method of claim 14.

17. A transfer machine comprising:
a substrate gripper that loads and unloads the substrate into and from a substrate holder that holds the substrate when the substrate is processed in a process chamber; and
an injector configured to be movable along a longitudinal direction of a column of the substrate holder and inject gas toward the column,
wherein the injector has an injection hole that is concentric with a center of the substrate held by the substrate holder and is configured to be able to inject the gas for cleaning toward the column from a tangential direction of an edge passing through the column.
